(19) United States
(12) Patent Application Publication
(10) Pub. No.: US 2026/0143844 A1
(43) Pub. Date: May 21, 2026

(54) PHOTOELECTRIC CONVERSION APPARATUS, EQUIPMENT, AND METHOD OF MANUFACTURING PHOTOELECTRIC CONVERSION APPARATUS

(71) Applicant: CANON KABUSHIKI KAISHA, Tokyo (JP)

(72) Inventor: Takuya Hara, Kanagawa (JP)

(21) Appl. No.: 19/449,969

(22) Filed: Jan. 15, 2026

Related U.S. Application Data
(62) Division of application No. 18/054,224, filed on Nov. 10, 2022.

(30) Foreign Application Priority Data
Dec. 14, 2021 (JP) 2021-202774

(51) Int. Cl. H10F 39/00

(52) U.S. Cl. CPC H10F 39/809; H10F 39/018; H10F 39/026; H10F 39/807

(57) ABSTRACT

A photoelectric conversion apparatus is provided. The apparatus comprises a first substrate in which photoelectric conversion elements are arranged, and a second substrate stacked on the first substrate, in which transistors configured to operate the photoelectric conversion elements are arranged. The first substrate comprises a first surface located on a side of the second substrate, and a second surface located on an opposite side of the first substrate. A dielectric embedded in a trench extending through the first substrate is arranged in the first substrate, and the dielectric comprises a third surface located on the side of the second substrate, and a fourth surface located on an opposite side of the third surface. The fourth surface is located between a virtual plane including the second surface and a virtual plane including the first surface.

### CROSS-REFERENCE TO RELATED APPLICATIONS

This application is a divisional application of U.S. patent application Ser. No. 18/054,224, filed Nov. 10, 2022, which claims the benefit of Japanese Patent Application No. 2021-202774, filed Dec. 14, 2021. All of these prior applications are hereby incorporated by reference herein in their entirety.

### BACKGROUND OF THE INVENTION

### Field of the Invention

The present invention relates to a photoelectric conversion apparatus, an equipment, and a method of manufacturing the photoelectric conversion apparatus.

### Description of the Related Art

In a photoelectric conversion apparatus such as an image sensor, in order to decrease the size and increase the functions, a back-side illumination type photoelectric conversion apparatus is sometimes used. Japanese Patent Laid-Open No. 2006-128392 describes that when manufacturing a back-side illumination type solid-state imaging sensor, a terminating detection portion having a hardness higher than that of a semiconductor substrate is embedded on the side of the front surface of the semiconductor substrate, and the semiconductor substrate is thinned from the back surface by chemical mechanical polishing until the terminating detection portion is exposed.

### SUMMARY OF THE INVENTION

In the thinning process described in Japanese Patent Laid-Open No. 2006-128392, due to the influence of a stress generated around the terminating detection portion of the semiconductor substrate upon exposing the terminating detection portion, a defect may be generated in the light receiving surface of the photoelectric conversion element. The defect in the light receiving surface of the photoelectric conversion element can cause a decrease in characteristics of the photoelectric conversion apparatus.

Some embodiments of the present invention provide a technique advantageous in improving the characteristics of a photoelectric conversion apparatus.

According to some embodiments, a photoelectric conversion apparatus comprising a first substrate in which a plurality of photoelectric conversion elements are arranged, and a second substrate stacked on the first substrate, in which a plurality of transistors configured to operate the plurality of photoelectric conversion elements are arranged, wherein the first substrate comprises a first surface located on a side of the second substrate, and a second surface located on an opposite side of the first substrate, a dielectric embedded in a trench extending through the first substrate is further arranged in the first substrate, the dielectric comprises a third surface located on the side of the second substrate, and a fourth surface located on an opposite side of the third surface, and the fourth surface is located between a virtual plane including the second surface and a virtual plane including the first surface, is provided.

According to some other embodiments, a method of manufacturing a photoelectric conversion apparatus comprising a first substrate in which a plurality of photoelectric conversion elements are arranged, and a second substrate stacked on the first substrate, comprising: preparing a structure in which the first substrate and the second substrate are stacked; and thinning the first substrate of the structure, wherein the first substrate comprises a first surface located on a side of the second substrate, and a second surface located on an opposite side of the first substrate, a trench is arranged in the first surface, a dielectric comprising a third surface located on the side of the second substrate is embedded in the trench, the thinning the first substrate comprises: thinning the first substrate until the dielectric is exposed from the side of the second surface; etching the dielectric from the side of the second surface, after the thinning the first substrate until the dielectric is exposed, such that a fourth surface located on an opposite side of the third surface of the dielectric after the etching is located between a virtual plane including a surface of the first substrate exposed by the thinning the first substrate until the dielectric is exposed and a virtual plane including the first surface; and polishing, after the etching the dielectric, the first substrate from a side of the surface of the first substrate exposed by the thinning the first substrate until the dielectric is exposed from the side of the second surface, and in the polishing the first substrate, the thinning is terminated in a state in which the fourth surface is located between a virtual plane including a surface of the first substrate exposed by the polishing the first substrate and the virtual plane including the first surface, is provided.

Further features of the present invention will become apparent from the following description of exemplary embodiments (with reference to the attached drawings).

### BRIEF DESCRIPTION OF THE DRAWINGS

FIG. 1 is a sectional view showing an arrangement example of a photoelectric conversion apparatus according to an embodiment;

FIG. 2 is a view showing a modification of the photoelectric conversion apparatus shown in FIG. 1;

FIGS. 3A and 3B are sectional views showing a method of manufacturing the photoelectric conversion apparatus shown in FIG. 1;

FIGS. 4A and 4B are sectional views showing the method of manufacturing the photoelectric conversion apparatus shown in FIG. 1; and

FIG. 5 is a view showing an arrangement example of an equipment incorporating the photoelectric conversion apparatus according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

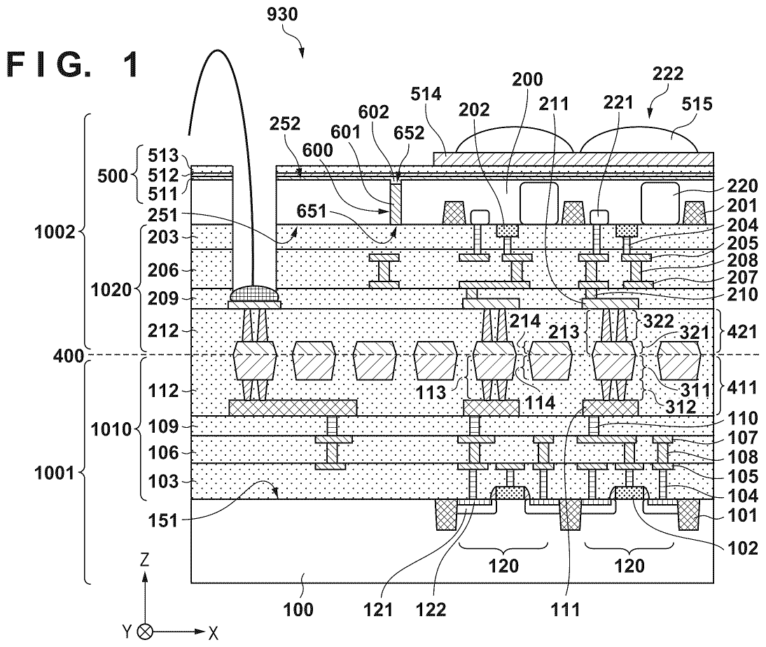

With reference to FIGS. 1 to 5, a photoelectric conversion apparatus according to an embodiment of the present disclosure will be described. FIG. 1 is a sectional view showing an arrangement example of a photoelectric conversion apparatus 930 according to this embodiment. The photoelectric conversion apparatus 930 includes a substrate 200 in which a plurality of photoelectric conversion elements 222 are arranged, and a substrate 100 stacked on the substrate 200, in which a plurality of transistors 120 for operating the plurality of photoelectric conversion elements 222 are arranged. A semiconductor such as silicon is used for the substrate 100 and the substrate 200.

A wiring structure 1010 including a wiring pattern is arranged on a surface 151 located on the substrate 200 side of the substrate 100. The wiring structure 1010 forms a semiconductor component 1001 together with the substrate 100 and the transistors 120 arranged in the surface 151 of the substrate 100. A wiring structure 1020 including a wiring pattern is arranged on a surface 251 located on the substrate 100 side of the substrate 200. The wiring structure 1020 forms a semiconductor component 1002 together with the substrate 200 and the like.

In this embodiment, the substrate 200 has a thickness of, for example, about 2 μm to 9 μm. The semiconductor component 1001 and the semiconductor component 1002 overlap each other, and are bonded to each other at a bonding surface 400. In a direction Z in which the substrate 100 and the substrate 200 are stacked, an insulating film 112 of the semiconductor component 1001 (wiring structure 1010) and an insulating film 212 of the semiconductor component 1002 (wiring structure 1020) are stacked so as to be located between the substrate 100 and the substrate 200. In the wiring structure 1010, each of a plurality of conductive portions 113 is arranged in each of a plurality of concave portions provided in the insulating film 112. In the wiring structure 1020, each of a plurality of conductive portions 213 is arranged in each of a plurality of concave portions provided in the insulating film 212. The semiconductor component 1001 and the semiconductor component 1002 are bonded to each other by the conductive portions 113 arranged in the concave portions provided in the insulating film 112 and the conductive portions 213 arranged in the concave portions provided in the insulating film 212.

A plane intersecting the direction Z is defined as an X-Y plane. The direction Z and the X-Y plane can intersect perpendicularly. The X-Y plane is a plane parallel to at least one of the surface 151 of the substrate 100 and the surface 251 of the substrate 200. A direction X and a direction Y are orthogonal to each other, and parallel to at least one of the surface 151 of the substrate 100 and the surface 251 of the substrate 200. FIG. 1 shows a view obtained by cutting the photoelectric conversion apparatus 930 in the direction (direction Z) in which the substrate 100 and the substrate 200 are stacked.

Each conductive portion 113 is formed by including a pad 311 surrounded by the insulating film 112 in the X-Y plane, and a plug 312 connecting to the pad 311 so as to be located between the pad 311 and the substrate 100 in the direction Z. The plug 312 is connected to a conductive layer 111 located between the plug 312 and the substrate 100 in the direction Z. The conductive layer 111 is close to the plug 312.

Each conductive portion 213 is formed by including a pad 321 surrounded by the insulating film 212 in the X-Y plane, and a plug 322 connecting to the pad 321 so as to be located between the pad 321 and the substrate 200 in the direction Z. The plug 322 is connected to a conductive layer 211 located between the plug 322 and the substrate 200 in the direction Z. The conductive layer 211 is close to the plug 322.

The semiconductor component 1001 is a semiconductor component (semiconductor chip) including the substrate 100 and the wiring structure 1010, and the semiconductor component 1002 is a semiconductor component (semiconductor chip) including the substrate 200 and the wiring structure 1020. As will be described later, each of the wiring structure 1010 and the wiring structure 1020 includes a plurality of stacked wiring layers and a plurality of stacked insulating films. Accordingly, a portion obtained by bonding the wiring structure 1010 and the wiring structure 1020 can also be referred to as a wiring structure portion in the photoelectric conversion apparatus 930. The photoelectric conversion apparatus 930 is formed by bonding the semiconductor component 1001 and the semiconductor component 1002.

A structure between the substrate 100 and the semiconductor component 1002 (between the substrate 100 and the wiring structure 1020) is the wiring structure 1010. The wiring structure 1010 includes the above-described conductive portions 113 and conductive layer 111. In addition to the conductive portions 113 and the conductive layer 111, the wiring structure 1010 can include a plug 110, a wiring layer 107, a plug 108, a wiring layer 105, a plug 104, and the like arranged between the conductive layer 111 and the substrate 100. The wiring structure 1010 also includes the above-described insulating film 112. In addition to the insulating film 112, the wiring structure 1010 can include insulating films 109, 106, and 103 arranged between the insulating film 112 and the substrate 100. However, the arrangement of the wiring structure 1010 is not limited to the structure shown in FIG. 1, and the numbers and arrangements of the wiring layers, plugs, and insulating films may be adjusted as appropriate in accordance with the function and performance required for the photoelectric conversion apparatus 930.

A structure between the substrate 200 and the semiconductor component 1001 (between the substrate 200 and the wiring structure 1010) is the wiring structure 1020. The wiring structure 1020 includes the above-described conductive portions 213 and conductive layer 211. In addition to the conductive portions 213 and the conductive layer 211, the wiring structure 1020 can include a plug 210, a wiring layer 207, a plug 208, a wiring layer 205, a plug 204, and the like arranged between the conductive layer 211 and the substrate 200. The wiring structure 1020 also includes the above-described insulating film 212. In addition to the insulating film 212, the wiring structure 1020 can include insulating films 209, 206, and 203 arranged between the insulating film 212 and the substrate 200. However, the arrangement of the wiring structure 1020 is not limited to the structure shown in FIG. 1, and the numbers and arrangements of the wiring layers, plugs, and insulating films may be adjusted as appropriate in accordance with the function and performance required for the photoelectric conversion apparatus 930.

The conductive layers 111 and 211 can also be referred to as wiring layers, but in order to discriminate the wiring layers close to the plugs 312 and 322, respectively, from other wiring layers, they are referred to as the conductive layers 111 and 211. The plug 208 connects the wiring layer 205 and the wiring layer 207, and the plug 210 connects the wiring layer 207 and the conductive layer 211. The conductive portion 213 can have a damascene structure embedded in the concave portion provided in the insulating film 212. At least a part of the conductive portion 213 is connected to the conductive layer 211. In this embodiment, the conductive portion 213 has a dual damascene structure, and is formed by the pad 321 and the plug 322. The semiconductor component 1001 and the semiconductor component 1002 are electrically connected by the conductive portions 113 and the conductive portions 213.

The main component of each of the conductive portion 113 and the conductive portion 213 may be copper, but the present invention is not limited to this. The main component of each of the conductive portion 113 and the conductive portion 213 may be gold or silver. The main component of each of the insulating film 112 and the insulating film 212 can be a silicon compound such as silicon oxide, silicon nitride, silicon oxynitride, or the like. Each of the insulating film 112 and the insulating film 212 may be formed by a plurality of layers made of different materials, such as a stacked structure in which a layer (for example, a silicon nitride layer) that suppresses metal diffusion and a silicon oxide layer or a low-k material layer are stacked. By arranging the layer that suppresses metal diffusion, it is possible to suppress the influence of metal diffusion caused by a bonding deviation between the conductive portion 113 and the conductive portion 213 which occurs due to an alignment deviation generated upon bonding the semiconductor component 1001 and the semiconductor component 1002. Also, for example, the main component of each of the insulating film 112 and the insulating film 212 may be a resin.

Here, the conductive portion 113 and the insulating film 112 are collectively referred to as a bonding member 411, and the conductive portion 213 and the insulating film 212 are collectively referred to as a bonding member 421. The bonding member 411 included in the semiconductor component 1001 and the bonding member 421 included in the semiconductor component 1002 are bonded to each other. The plug 104, the wiring layers 105 and 107, the conductive layer 111, the conductive portions 113 and 213, the conductive layer 211, the wiring layers 207 and 205, and the plug 204 are electrically continuous from the substrate 100 to the substrate 200. These components form a conductive pattern (interlayer wiring pattern) between the substrate 100 and the substrate 200. One end of the interlayer wiring pattern may be connected to the gate electrode of the transistor 120 and the other end may be connected to the source/drain of the transistor 120. Also, one end and the other end of the interlayer wiring pattern may be connected to the source and drain of the transistor 120, respectively.

In the photoelectric conversion apparatus 930, the wiring structure 1010 and the wiring structure 1020 are bonded. More specifically, the wiring structure 1010 and the wiring structure 1020 are bonded at the bonding surface 400 formed by the bonding member 411 of the wiring structure 1010 and the bonding member 421 of the wiring structure 1020. The bonding surface 400 includes the surface of the bonding member 411 and the surface of the bonding member 421.

An element separation portion 101 and the plurality of transistors 120 are provided in the surface 151 of the substrate 100. The surface 151 of the substrate 100 is sometimes referred to as the main surface of the substrate 100. In the photoelectric conversion apparatus 930, an integrated circuit of the substrate 100 can include signal processing circuits for processing a pixel signal, such as an analog signal processing circuit, an A/D conversion circuit, a noise removing circuit, and a digital signal processing circuit. That is, at least a part of the plurality of transistors 120 may form a digital signal processing circuit for performing digital processing on signals output from the plurality of photoelectric conversion elements 222 of the substrate 200. The substrate 100 can be referred to as a “semiconductor layer”.

The element separation portion 101 has an STI (Shallow Trench Isolation) structure, and defines the element region (active region) of the substrate 100. The plurality of transistors 120 can form, for example, a CMOS circuit. A source/drain 121 of the transistor 120 can include a silicide layer 122 of cobalt silicide, nickel silicide, or the like. Accordingly, the conductive portion 113 is electrically connected to the substrate 100 via the silicide layer 122. More specifically, the plug 104 electrically connected to the conductive portion 113 is in contact with the silicide layer 122 formed between the interlayer insulating film 103 and the substrate 100 by a silicide process. As compared to a case in which the conductive portion 113 is electrically connected to the substrate 100 without intervening the silicide layer, the contact resistance can be low when the conductive portion 113 is electrically connected to the substrate 100 via the silicide layer 122. A gate electrode 102 of the transistor 120 can include a silicide layer, a metal layer, and a metal compound layer. For the gate insulating film of the transistor 120, a metal oxide such as silicon oxide, silicon nitride, hafnium oxide, or the like can be used.

In the surface 251 of the substrate 200, a trench 600 extending through the substrate 200, an element separation portion 201, a gate electrode 202, a photoelectric conversion portion 220, a floating diffusion 221, and the like are provided. The photoelectric conversion portion 220 is formed by a photodiode and a photogate. The photodiode may be an avalanche diode. Of the surfaces of the substrate 200, the surface in which a plurality of transistors are provided is the main surface of the substrate 200. The surface 251 located on the substrate 100 side of the substrate 200 is sometimes referred to as the main surface of the substrate 200. The substrate 200 can be referred to as a “semiconductor layer”.

A dielectric 601 is embedded in the trench 600 extending through the substrate 200. The dielectric 601 includes a surface 651 located on the substrate 100 side, and a surface 652 located on the opposite side of the surface 651. The dielectric 601 includes, for example, silicon nitride. However, the present invention is not limited to this. For the dielectric 601, for example, a material having a hardness higher than that of the substrate 200 can be used. As shown in FIG. 1, the surface 651 of the dielectric may be arranged on the same plane as the surface 251 of the substrate 200. That is, on the side of the surface 251 of the substrate 200, the inner wall of the trench 600 may not be exposed. On the other hand, the surface 652 of the dielectric 601 is located between a virtual plane including a surface 252 of the substrate 200 and a virtual plane including the surface 251 of the substrate 200. Therefore, the inner wall of the trench 600 from the height of the surface 252 of the substrate 200 to the height where the surface 652 of the dielectric 601 is arranged is not covered by the dielectric 601 (concave region 602). On the side of the surface 252 of the substrate 200, the surface (surface 652) of the dielectric 601 is recessed from the surface 252 of the surface 200. The arrangement between the trench 600 and the dielectric 601 will be described later.

The element separation portion 201 has, for example, an STI structure, and defines the element region (active region) of the substrate 200. The gate electrode 202 transfers electric charges of the photoelectric conversion portion 220 to the floating diffusion 221. The substrate 200 is also provided with a pixel circuit that converts the electric charges generated in the photoelectric conversion portion 220 into a pixel signal. The pixel circuit can include a reset transistor, an amplification transistor, a selection transistor, and the like. The pixel signal corresponding to the electric charges transferred to the floating diffusion 221 is generated by the amplification transistor. The potential of the floating diffusion 221 is reset to the reset potential by the reset transistor. The photoelectric conversion element 222 described above includes the photoelectric conversion portion 220, the gate electrode 202, the floating diffusion 221, and the pixel circuit for them.

As has been described above, the conductive portion 113 is electrically connected to the substrate 100 via the silicide layer 122. On the other hand, the conductive portion 213 is electrically connected to the substrate 200 without intervening a silicide layer. In this embodiment, the plug 204 electrically connected to the conductive portion 213 is in contact (ohmic contact) with the impurity region of the substrate 200 formed without performing a silicide process. However, the present invention is not limited to this, and the plug 204 may be electrically connected to the substrate 200 via a silicide layer of titanium silicide, tungsten silicide, or the like locally formed below the plug 204.

In this embodiment, the semiconductor component 1001 includes a digital circuit, and the semiconductor component 1002 includes an analog circuit. However, the semiconductor component 1001 may include an analog circuit, and the semiconductor component 1002 may include a digital circuit. The photoelectric conversion portion 220 provided in the substrate 200 is connected to the floating diffusion 221 via the gate electrode 202. The floating diffusion 221 is connected to the gate electrode of a source follower transistor of the pixel circuit described above. An analog pixel signal is output from the source of the source follower transistor. The pixel circuit including the gate electrode 202 and the source follower transistor can be the analog circuit included in the semiconductor component 1002. The analog pixel signal is A/D-converted into a digital pixel signal by an A/D conversion circuit. The digital pixel signal undergoes signal processing by a digital signal processing circuit (DSP). The digital signal processing circuit that performs image processing can be an image processing circuit (ISP). The digital signal processing circuit can be a circuit arranged in the semiconductor component 1001. In addition to this, examples of the digital circuits arranged in the semiconductor component 1002 are interface circuits such as low voltage differential signaling (LVDS) and a mobile industry processor interface (MIPI).

In the photoelectric conversion apparatus 930 according to this embodiment, a dielectric film 500 including a dielectric 511, a dielectric 512, and dielectric 513 is arranged on the surface 252 of the substrate 200. The dielectric film 500 may have a stacked structure including the multiple dielectrics 511 to 513 as shown in FIG. 1, or may have a single layer structure.

The dielectric 511 of the dielectric film 500 is arranged so as to be in contact with the surface 652 of the above-described dielectric 601 in the trench 600. Further, in the concave region 602 of the substrate 200 which is exposed since the surface 652 of the dielectric 601 is located between the virtual plane including the surface 252 of the substrate 200 and the virtual plane including the surface 251, the dielectric 511 is in contact with the inner wall of the trench 600.

A metal oxide having a negative fixed charge may be used as the dielectric 511. By arranging the dielectric 511 having the negative fixed charge near the substrate 200, noise caused by electrons generated near the substrate 200 can be reduced. For the dielectric 511 having the negative fixed charge, for example, a material such as hafnium oxide, aluminum oxide, zirconium oxide, titanium oxide, tantalum oxide, or ruthenium oxide is used. For example, the dielectric 511 may be hafnium oxide or aluminum oxide. The thickness of the dielectric 511 can be, for example, 5 nm to 20 nm. In the arrangement shown in FIG. 1, the dielectric 511 is arranged so as to cover the surface 252 of the substrate 200. Further, the dielectric 511 is in contact with the substrate 200. However, the present invention is not limited to this, and another dielectric having a thickness less than 10 nm may be arranged between the dielectric 511 and the surface 252 of the substrate 200. For example, silicon oxide less than 10 nm may be arranged between the surface 252 of the substrate 200 and the dielectric 511 formed of hafnium oxide or the like.

The dielectric 512 can have a function as an antireflection layer. When the dielectric 512 is used as the antireflection layer, the thickness of the dielectric 512 may be larger than the thickness of the dielectric 511. When the dielectric 512 is used as the antireflection layer, the thickness of the dielectric 512 can be, for example, in a range of 20 nm to 100 nm. As the dielectric 512, a metal oxide layer of hafnium oxide, aluminum oxide, zirconium oxide, titanium oxide, tantalum oxide, ruthenium oxide, or the like can be used. A silicon compound such as silicon oxide, silicon nitride, or silicon oxynitride may be used for the dielectric 512. Since tantalum oxide has a high dielectric constant among these dielectrics, tantalum oxide may be used for the dielectric 512 that functions as the antireflection layer.

In order to give the appropriate antireflection performance to the dielectric 512, a material having a refractive index lower than that of the dielectric 512 is used for the dielectric 513. For the dielectric 513, a silicon compound such as silicon oxide, silicon nitride, or silicon oxynitride may be used, or a resin material may be used.

A color filter 514 and a micro lens 515 are arranged on the dielectric film 500. Further, for example, a light shielding film for forming an optical black (OB) region using a metal such as tungsten may be provided between the dielectric film 500 and the color filter 514 and microlens 515. In addition, for example, a light shielding wall for light separation between the photoelectric conversion elements 222 may be provided in the dielectric film 500 and the color filter 514.

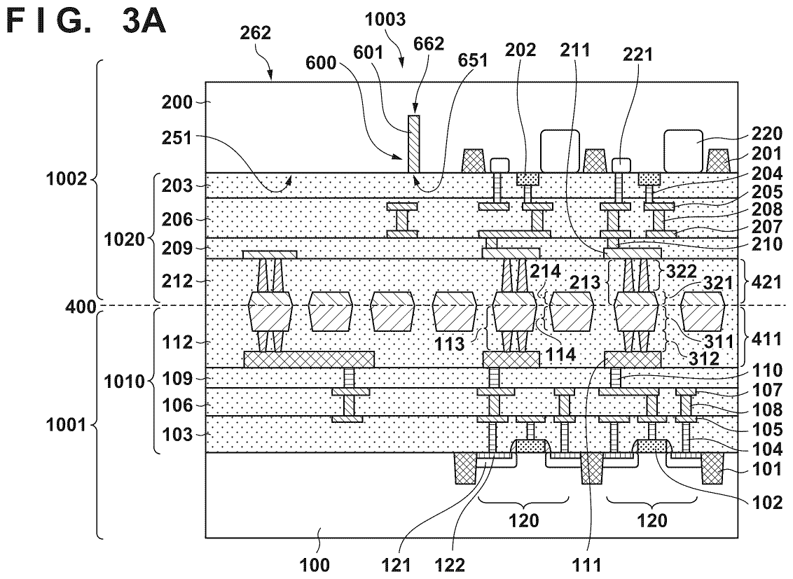

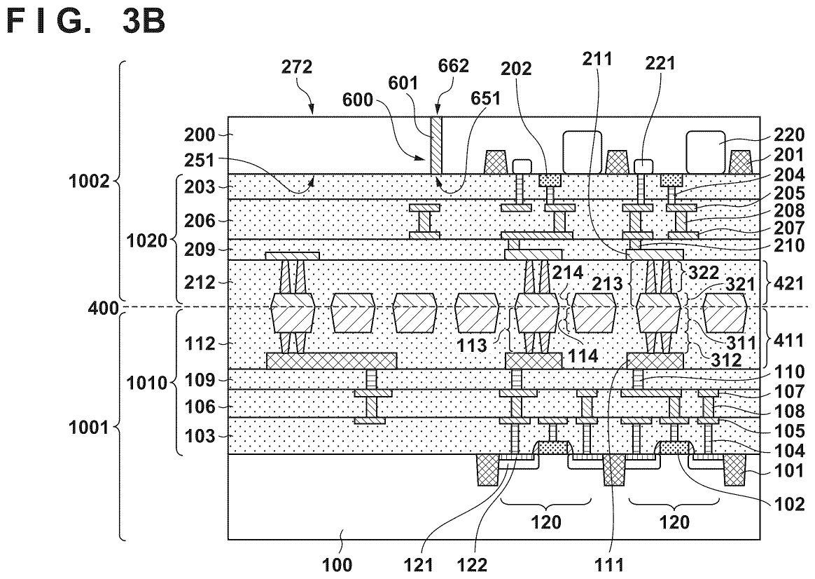

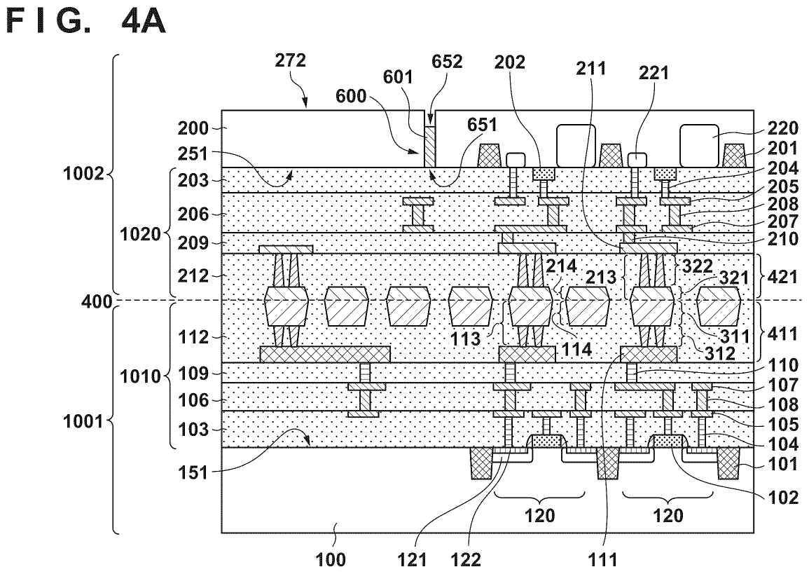

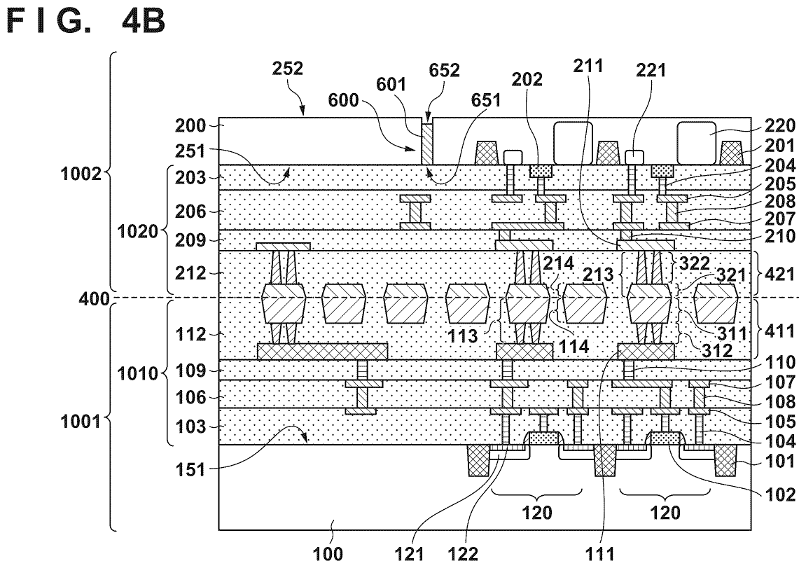

In this embodiment, the dielectric 601 embedded in the trench 600 extending through the substrate 200 is recessed from the surface 251 of the substrate 200, and the surface 652 of the dielectric 601 is located between the virtual plane including the surface 252 of the substrate 200 and the virtual plane including the surface 252. The effect generated by employing the arrangement described above will be described below with reference to FIGS. 3A to 4B. FIGS. 3A to 4B are views showing a method of manufacturing the photoelectric conversion apparatus 930.

First, as shown in FIG. 3A, the semiconductor component 1001 including the substrate 100 and the semiconductor component 1002 including the substrate 200 are bonded to each other at the bonding surface 400 to prepare a structure 1003 in which the substrate 100 and the substrate 200 are stacked. Then, a thinning process of thinning the substrate 200 of the structure 1003 is performed. By undergoing the thinning process of removing a part of the substrate 200 from the side of a surface 262 of the substrate 200 located on the opposite side of the surface 151 of the substrate 100, the above-described surface 252 of the substrate 200 becomes the light receiving surface of the photoelectric conversion apparatus 930.

After the structure 1003 is prepared, as shown in FIG. 3B, the substrate 200 is first thinned from the surface 262 side. For the process shown in FIG. 3B, a mechanical polishing method may be used, or a chemical mechanical polishing (CMP) method may be used. Also, in the process shown in FIG. 3B, a wet etching method may be used. As shown in FIG. 3B, the substrate 200 is thinned until the dielectric 601 embedded in the trench 600 formed in the surface 251 of the substrate 200 is exposed. By the process shown in FIG. 3B, a surface 272 of the substrate 200 is exposed together with a surface 662 of the dielectric 601. The surface 272 of the substrate 200 and the surface 662 of the dielectric 601 may be arranged on the same plane. Also, the dielectric 601 may have a convex shape protruding from the surface 272 of the substrate 200.

Then, as shown in FIG. 4A, a part of the dielectric 601 is etched such that the surface of the dielectric 601 is recessed from the surface 272 of the substrate 200 exposed by the process shown in FIG. 3B. That is, the dielectric 601 is etched from the side of the surface 272 of the substrate 200 such that the surface 652 located on the opposite side of the surface 651 of the dielectric 601 after etching is located between a virtual plane including the surface 272 of the substrate 200 exposed by the process shown in FIG. 3B and the virtual plane including the surface 251 of the substrate 200. In this process, the dielectric 601 may be etched by wet etching. A suitable etching solution capable of selectively etching the dielectric 601 can be used in accordance with the combination of the material of the substrate 200 and the material of the dielectric 601.

After etching the dielectric 601, as shown in FIG. 4B, an additional thinning process (to be sometimes referred to as an additional process hereinafter) of further thinning the substrate 200 from the side of the surface 272 of the substrate 200 exposed by the process shown in FIG. 3B is performed. For the additional process, for example, chemical mechanical polishing is used. In this additional process, the thinning is terminated in a state in which the surface 652 of the dielectric 601 exposed by the etching shown in FIG. 4A is located between the virtual plane including the surface of the substrate 200 (the surface 252 of the substrate 200) exposed by the additional process and the virtual plane including the surface 251 of the substrate 200. That is, thinning of the substrate 200 is terminated in a state in which the surface (surface 652) of the dielectric 601 is recessed from the surface 252 of the substrate 200. In the additional process, for example, by processing while optically monitoring the film thickness of the substrate 200, it is possible to terminate the polishing in the state in which the surface 652 of the dielectric 601 is recessed from the surface 252 of the substrate 200. However, the present invention is not limited to this, and the thinning may be terminated in the state in which the surface 652 of the dielectric 601 is located between the virtual plane including the surface 252 of the substrate 200 and the virtual plane including the surface 251 of the substrate 200 by combining a process condition and a process time.

If the dielectric 601 has a convex shape protruding from the surface 252 of the substrate 200 during chemical mechanical polishing in the additional process, the dielectric 601 may be damaged during the polishing, or a stress may be generated between the substrate 200 and the dielectric 601 due to a force applied to the dielectric 601 by the polishing. The damage of the dielectric 601 and the stress between the substrate 200 and the dielectric 601 can cause a defect around the trench 600 of the substrate 200. Since the surface 252 of the substrate 200 serves as the light receiving surface of the photoelectric conversion element 222, if a defect is generated in the surface 252, this can cause a decrease in characteristics of the photoelectric conversion apparatus 930.

Meanwhile, in this embodiment, as shown in FIG. 4B, the dielectric 601 embedded in the trench 600 is arranged at the position recessed from the surface 252 of the substrate 200 in this additional process. Therefore, in the additional process, it is possible to suppress a defect of the substrate 200 caused by polishing the dielectric 601. That is, it is possible to suppress generation of a defect of the surface 252 serving as the light receiving surface of the substrate 200, thereby improving the characteristics of the photoelectric conversion apparatus 930.

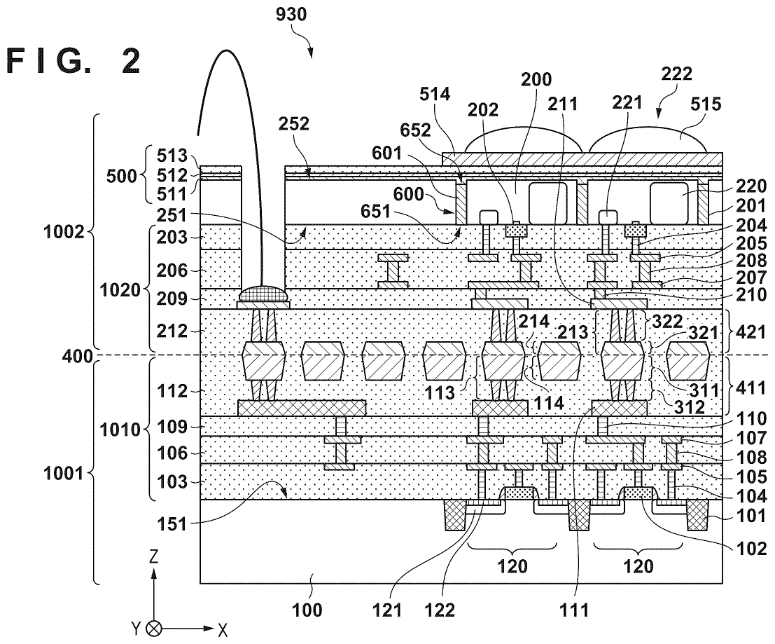

FIG. 2 is a sectional view showing a modification of the photoelectric conversion apparatus 930 shown in FIG. 1. As shown in FIG. 2, the substrate 200 is provided with the trench 600 extending through the substrate 200, and the dielectric 601 using, for example, silicon nitride is embedded in the trench 600. By forming the trench 600 in the surface 251 of the substrate 200, embedding the dielectric 601 in the trench 600, and using the above-described thinning process, it is possible to form the trench 600 extending through the substrate 200 in which the dielectric 601 is embedded at the position recessed from the surface 252 of the substrate 200.

As shown in FIG. 2, in this embodiment, by arranging the trench 600 so as to separate the photoelectric conversion elements 222 adjacent to each other, the photoelectric conversion elements 222 adjacent to each other are electrically separated by the dielectric 601 embedded in the trench 600. That is, the dielectric 601 functions as an element separation region between the plurality of photoelectric conversion elements 222. With this, it is possible to suppress that electric charges generated in the photoelectric conversion element 222 (photoelectric conversion portion 220) leak to the adjacent photoelectric conversion element 222. Further, since the dielectric 601 embedded in the trench 600 is recessed from the surface 252 of the substrate 200, an increase in dark current caused by the stress of an embedded film is suppressed. In this manner, also in this embodiment, it is possible to suppress generation of a defect of the surface 252 serving as the light receiving surface of the substrate 200, thereby improving the characteristics of the photoelectric conversion apparatus 930.

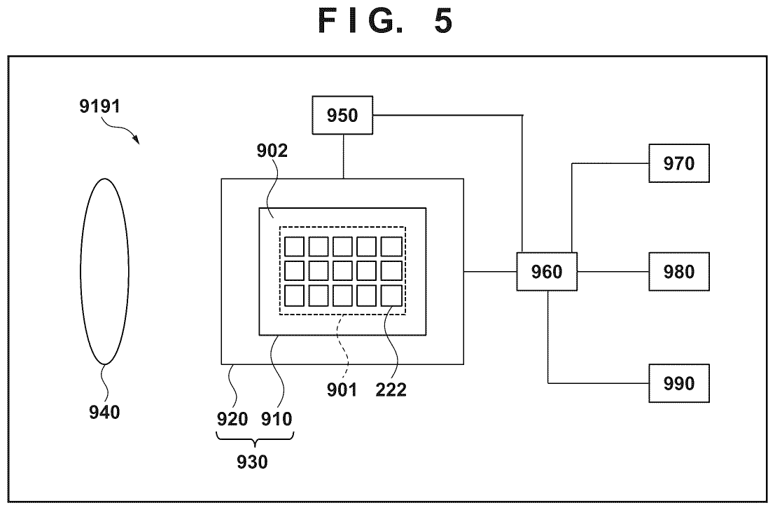

With reference to FIG. 5, an application example of the photoelectric conversion apparatus 930 according to this embodiment will be described. FIG. 5 is a schematic view of an equipment 9191 including the photoelectric conversion apparatus 930. In addition to a semiconductor device 910 including the above-described semiconductor component 1001 and semiconductor component 1002, the photoelectric conversion apparatus 930 can include a package 920 that accommodates the semiconductor device 910. However, the photoelectric conversion apparatus 930 may not include the package 920. The substrate 100 and the substrate 200 are included in the semiconductor device 910. In this embodiment, the photoelectric conversion apparatus 930 is a photoelectric conversion apparatus (imaging apparatus). The semiconductor device 910 includes a pixel region 901, in which the photoelectric conversion elements 222 are arrayed in a matrix, and a peripheral region 902 around the pixel region 901. Peripheral circuits and input/output terminals can be provided in the peripheral region 902. The equipment 9191 can include at least any of an optical apparatus 940, a control apparatus 950, a processing apparatus 960, a display apparatus 970, a storage apparatus 980, and a mechanical apparatus 990.

Hereinafter, the equipment 9191 including the photoelectric conversion apparatus 930 shown in FIG. 5 will be described in detail. As has been described above, in addition to the semiconductor device 910 including the substrate 100, the photoelectric conversion apparatus 930 can include the package 920 accommodating the semiconductor device 910. The package 920 can include a base on which the semiconductor device 910 is fixed, and a lid made of glass or the like facing the semiconductor device 910. The package 920 can further include bonding members such as a bonding wire and bump for connecting a terminal of the base and a terminal of the semiconductor device 910.

The equipment 9191 can include at least any of the optical apparatus 940, the control apparatus 950, the processing apparatus 960, the display apparatus 970, the storage apparatus 980, and the mechanical apparatus 990. The optical apparatus 940 corresponds to the photoelectric conversion apparatus 930. The optical apparatus 940 is implemented by, for example, a lens, a shutter, and a mirror. The control apparatus 950 controls the photoelectric conversion apparatus 930. The control apparatus 950 is, for example, a semiconductor apparatus such as an ASIC.

The processing apparatus 960 processes a signal output from the photoelectric conversion apparatus 930. The processing apparatus 960 is a semiconductor apparatus such as a CPU or ASIC for forming an AFE (Analog Front End) or a DFE (Digital Front End). The display apparatus 970 is an EL display apparatus or liquid crystal display apparatus that displays information (image) obtained by the photoelectric conversion apparatus 930. The storage apparatus 980 is a magnetic device or semiconductor device that stores the information (image) obtained by the photoelectric conversion apparatus 930. The storage apparatus 980 is a volatile memory such as an SRAM or DRAM or a nonvolatile memory such as a flash memory or hard disk drive.

The mechanical apparatus 990 includes a moving or propulsion unit such as a motor or engine. The equipment 9191 displays the signal output from the photoelectric conversion apparatus 930 on the display apparatus 970 and performs external transmission by a communication apparatus (not shown) of the equipment 9191. For this purpose, the equipment 9191 may further include the storage apparatus 980 and the processing apparatus 960 in addition to the memory circuits and arithmetic circuits of the photoelectric conversion apparatus 930. The mechanical apparatus 990 may be controlled based on the signal output from the photoelectric conversion apparatus 930.

The equipment 9191 is suitable for an electronic equipment such as an information terminal (for example, a smartphone or a wearable terminal) having a shooting function, or a camera (for example, a lens interchangeable type camera, a compact camera, a video camera, or a surveillance camera). The mechanical apparatus 990 in the camera can drive the components of the optical apparatus 940 in order to perform zooming, an in-focus operation, and a shutter operation. Also, the mechanical apparatus 990 in the camera can move the photoelectric conversion apparatus 930 in order to perform an anti-vibration operation.

The equipment 9191 can also be a transportation equipment such as a vehicle, a ship, or a flying vehicle. The mechanical apparatus 990 in the transportation equipment can be used as a mobile apparatus. The equipment 9191 as the transportation equipment can be applied to the equipment that transports the photoelectric conversion apparatus 930, or the equipment that assists and/or automates driving (steering) by a shooting function. The processing apparatus 960 for assisting and/or automating driving (steering) can perform processing for operating the mechanical apparatus 990 as a mobile apparatus based on the information obtained by the photoelectric conversion apparatus 930. Also, the equipment 9191 may be a medical equipment such as an endoscope, a measurement equipment such as a distance measurement sensor, an analysis equipment such as an electron microscope, or an office equipment such as a copy machine.

The embodiments described above can be modified as appropriate without departing from the technical scope. The disclosure content of the present specification includes not only matters described in the present specification but also all matters that can be understood from the present specification and the attached drawings. The disclosure content of the present specification also includes a complement of the concept described in the present specification. That is, for example, if there is a description that “A is B” in the present specification, the present specification shall disclose that “A is not B” even if a description that “A is not B” is omitted. This is because, if the description “A is B” is provided, it is premised that a case of “A is not B” is considered.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A method of manufacturing a photoelectric conversion apparatus comprising a first substrate in which a plurality of photoelectric conversion elements are arranged, and a second substrate stacked on the first substrate, comprising:
preparing a structure in which the first substrate and the second substrate are stacked; and
thinning the first substrate of the structure,
wherein:
the first substrate comprises a first surface located on a side of the second substrate, and a second surface located on an opposite side of the first substrate;
a trench is arranged in the first surface;
a dielectric comprising a third surface located on the side of the second substrate is embedded in the trench;
the thinning the first substrate comprises:
thinning the first substrate until the dielectric is exposed from the side of the second surface;
etching the dielectric from the side of the second surface, after the thinning the first substrate until the dielectric is exposed, such that a fourth surface located on an opposite side of the third surface of the dielectric after the etching is located between a virtual plane including a surface of the first substrate exposed by the thinning the first substrate until the dielectric is exposed and a virtual plane including the first surface; and
polishing, after the etching the dielectric, the first substrate from a side of the surface of the first substrate exposed by the thinning the first substrate until the dielectric is exposed from the side of the second surface; and
in the polishing the first substrate, the thinning is terminated in a state in which the fourth surface is located between a virtual plane including a surface of the first substrate exposed by the polishing the first substrate and the virtual plane including the first surface.

2. The method according to claim 1, wherein the dielectric includes silicon nitride.

3. The method according to claim 1, wherein the photoelectric conversion apparatus comprises a peripheral region for connection to an outside of the photoelectric conversion apparatus, and the trench is arranged between the peripheral region and the plurality of photoelectric conversion elements.

4. The method according to claim 3, wherein a terminal and a bonding wire connected to the terminal are arranged in the peripheral region.

5. The method according to claim 4, wherein an opening is arranged in the peripheral region, and the terminal and the bonding wire are arranged in the opening.

6. The method according to claim 1, wherein:
the photoelectric conversion apparatus comprises a first semiconductor component and a second semiconductor component;
the first semiconductor component comprises the first substrate, a first conductive portion, and a first insulating film;
the second semiconductor component comprises the second substrate, a second conductive portion, and a second insulating film;
the first semiconductor component and the second semiconductor component are bonded at a joint surface;
the first conductive portion and the second conductive portion are directly bonded at the joint surface, and the first insulating film and the second insulating film are directly bonded at the joint surface; and
the trench overlaps with the first conductive portion and the second conductive portion.

7. The method according to claim 1, wherein the dielectric functions as an element separation region between the plurality of photoelectric conversion elements.

8. The method according to claim 1, wherein the dielectric serves as a first dielectric, and a second dielectric in contact with the fourth surface is arranged in the trench.

9. The method according to claim 8, wherein the second dielectric is in contact with an inner wall of the trench.

10. The method according to claim 8, wherein the second dielectric is arranged so as to cover the second surface.

11. The method according to claim 8, wherein the second dielectric includes a metal oxide.

12. The method according to claim 11, wherein the metal oxide includes at least one selected from the group consisting of hafnium oxide, aluminum oxide, zirconium oxide, titanium oxide, tantalum oxide, and ruthenium oxide.

13. The method according to claim 1, wherein the first surface and the third surface are arranged on a same plane.

14. The method according to claim 1, wherein a plurality of transistors configured to operate the plurality of photoelectric conversion elements are arranged in the second substrate, and at least a part of the plurality of transistors form a digital signal processing circuit configured to perform digital processing on signals output from the plurality of photoelectric conversion elements.

15. The method according to claim 1, wherein in the polishing the first substrate, the first substrate is polished while optically monitoring a film thickness of the first substrate.

16. The method according to claim 1, wherein in the etching the dielectric, the dielectric is etched by wet etching.

17. The method according to claim 1, wherein in the polishing the first substrate, the first substrate is polished by chemical mechanical polishing.

18. The method according to claim 1, wherein:
the dielectric and the trench serve as a first dielectric and a first trench;
a third dielectric embedded in a second trench extending through the first substrate is further arranged in the first substrate;
the third dielectric comprises a fifth surface located on the side of the second substrate, and a sixth surface located on an opposite side of the fifth surface, and
the sixth surface is located between the virtual plane including the second surface and the virtual plane including the first surface; and
the second trench is arranged between the plurality of photoelectric conversion elements.

19. The method according to claim 1, wherein the fourth surface is flat.

20. The method according to claim 1, wherein the dielectric has a hardness higher than the first substrate.
